(19) United States
(12) Patent Application Publication
(10) Pub. No.: US 2006/0268602 A1
(43) Pub. Date: Nov. 30, 2006

(54) Memory architecture for high density and fast speed

(75) Inventors: Tom Allen Agan, Plymouth, MN (US); James Chyi Lai, Plymouth, MN (US); Chien-Chiang Chan, Chung-Ho City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Northern Lights Semiconductor Corp.

(21) Appl. No.: 11/437,474

(22) Filed: May 19, 2006

Related U.S. Application Data
(60) Provisional application No. 60/683,997, filed on May 24, 2005.

(51) Int. Cl. G11C 11/00

(52) U.S. Cl. 365/158

(57) ABSTRACT

A memory comprises a plurality of memory units electrically connected. Each of the memory units comprises a pull-down transistor, a plurality of column lines and a selector. Each of the column lines has at least one bit. The selector is electrically connected between the pull-down transistor and the column lines. The selector is arranged to select one from the column lines to be accessed by the pull-down transistor. This results in a memory design that is faster, has more capability, is cheaper to build, quieter, and lower power.

### CROSS-REFERENCE TO RELATED APPLICATION

This application claims the priority benefit of U.S. Provisional Application Ser. No. 60/683,997, filed May 24, 2005, the full disclosures of which are incorporated herein by reference.

### BACKGROUND

1. Field of Invention

The present invention relates to memory architectures. More particularly, the present invention relates to a memory architecture of MRAM.

2. Description of Related Art

Magnetoresistive random access memory (MRAM) is a type of non-volatile memory with fast programming time and high density. The MRAM generally includes a plurality of MRAM cells placed on intersections of sense lines and word lines. A MRAM cell has two ferromagnetic layers separated by a non-magnetic layer. Information is stored as directions of magnetization vectors in the two ferromagnetic layers.

The resistance of the non-magnetic layer between the two ferromagnetic layers indicates a minimum value when the magnetization vectors of the two ferromagnetic layers point in substantially the same direction. On the other hand, the resistance of the non-magnetic layer between the two ferromagnetic layers indicates a maximum value when the magnetization vectors of the two ferromagnetic layers point in substantially opposite directions. Accordingly, a detection of changes in resistance allows information being stored in the MRAM cell.

The “N” words lines and the “M” sense lines intersect to form a memory array, i.e. an N×M matrix. An MRAM cell, one memory bit of the MRAM, is selected by providing one sense line current vertically in a column of the matrix and one word line horizontally in a row of the N×M matrix. In prior art, there exists a pull-down transistor, a so-called sense transistor, in each of the sense line for pulling down the sense line. The sense transistor is relatively large in order to be able to handle the currents necessary to access (both to read and to write) the memory bits without adding too much resistance.

It is the size of this transistor divided by the number of memory bits per sense line that determines the size of the MRAM. The density of MRAM is also dependent upon the number of memory bits per sense line, the resistance of the memory bit, the number of other transistors in series on the sense line, the power supply voltage and the metal resistance.

### SUMMARY

It is therefore an aspect of the present invention to provide a magnetoresistive memory, of which the size is reduced, the density is increased, and the performance is enhanced.

According to one preferred embodiment of the present invention, a magnetoresistive memory has a least one memory unit. The memory unit has a sense transistor, a plurality of sense lines and a selector. Each of the sense lines has at least one memory bit. The selector is electrically connected between the sense transistor and the sense lines. The selector is arranged to select one from the sense lines to be accessed by the sense transistor.

According to another preferred embodiment of the present invention, a magnetoresistive memory comprises a sense transistor and a plurality of sense lines. Each of the sense lines has a control logic and at least one memory bit. The control logic is electrically connected between the sense transistor and the memory bit.

It is another aspect of the present invention to provide a memory, which has a great capacity, a high density and a good performance.

According to another embodiment of the present invention, a memory comprises a plurality of memory units electrically connected. Each of the memory units comprises a pull-down transistor, a plurality of column lines and a selector. Each of the column lines has at least one bit. The selector is electrically connected between the pull-down transistor and the column lines. The selector is arranged to select one from the column lines to be accessed by the pull-down transistor.

By making a sense transistor do multiple duties, the size of the memory can be reduced and the performance thereof also can be improved significantly. Moreover, due to the decreasing of the sense transistors in the memory array, the number of the memory bits in each sense line can be increased. This also allows a significant increase in density of the memory.

It is to be understood that both the foregoing general description and the following detailed description are examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1A is a schematic view of one preferred embodiment of the present invention;

FIG. 1B is a schematic view of another preferred embodiment of the present invention demonstrating scalability; and

FIG. 2 is a schematic view of another preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The present invention leaves one sense transistor at the top of the sense lines and adds a selector to the sense lines of an MRAM. The number of the sense transistors in the MRAM is decreased, and thus increasing the number of the memory bits in each sense line and obtaining a significant increase in density of the MRAM. Moreover, by making the sense transistor do multiple duties, the size of the MRAM can be reduced and the performance also can be improved significantly.

First of all, an MRAM array having “M” sense lines and “N” word lines is assumed. The number ‘N’ of memory bits per sense line is determined by the resistance of the memory bits and the contacts to connect them as well as the voltage drops across the sense transistor. When the resistance of the memory bit is decreased, the number of memory bits per sense line can be increased. More precisely, one memory bit of the sense line is selected to provide a signal to a preamplifier by turning on a sense line current which goes to the memory bit in question as well as turning on a word line current under the memory bit. Therefore, an amount of percentage reduction in the sense line current due to the decreased resistance can provide an equal amount of percentage increase in density of the memory.

Moreover, metal resistance is a primary factor in determining the number “M” of sense lines per word line. Accordingly, as the resistance of the memory bits is decreased, more “N” memory bits can be connected in series in the sense line; as the metal line resistance is dropped, more “M” sense lines per word line can be made. Increasing the number “M” of the sense lines allows decreasing the required number of word line drivers. However, the space consumed by the word line drivers is not that large to have much effect on the overall density of the MRAM.

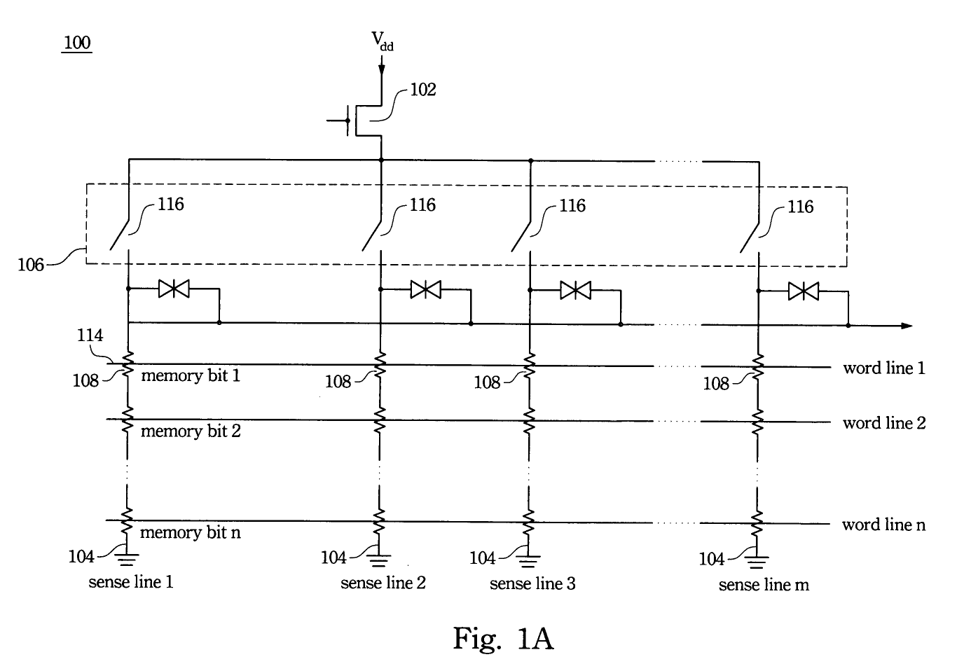

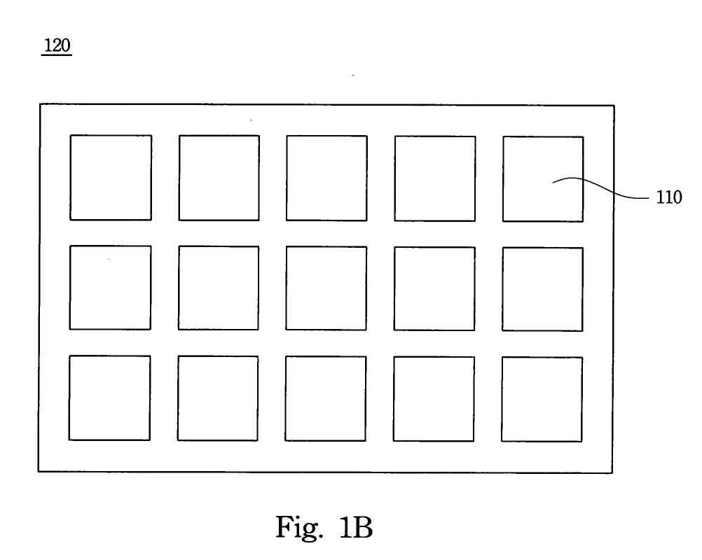

FIG. 1A is a schematic view of one preferred embodiment of the present invention. Compared to the conventional design, only one sense transistor is left and moved to the top end of sense lines and a bit of minimum sized control logic is added in each of the sense lines. The added control logic is very small in comparison to the size of the sense transistor connected at the top end of the sense lines. This allows an elimination of significant percentage of the multiple transistors in every path of the conventional design, and thus improving the density of the memory.

As illustrated in FIG. 1A, a magnetoresistive memory 100 has a sense transistor 102, a plurality of sense lines 104 and a selector 106. Each of the sense lines 104 has at least one memory bit 108. The selector 106 is electrically connected between the sense transistor 102 and the sense lines 104. The selector 106 is arranged to select one from the sense lines 104 to be accessed by the sense transistor 102.

Particularly, the magnetoresistive memory 100 has “M” sense lines 104 electrically connected in parallel, and the “M” is more than one, such as 128 or more. Each of the sense lines 104 has “N” memory bits 108 electrically connected in series, and the “N” is at least one, such as 16, 32 or more. The selector 106 is electrically connected to the “M” sense lines 104, and selects one of the “M” sense lines 104 for the sense transistor 102. The sense transistor 102 (i.e. the pull-down transistor) can access, such as reading and writing, the “N” memory bit 108 of the selected sense line 104.

The selector 106 can be a tree selector having multiple classes for dealing with a large number of sense lines 104. Alternatively, the selector 106 can comprise simple control logics 116 as illustrated in FIG. 1A for switching a small quantity of sense lines 104. One of the control logics 116 is electrically connected between the sense transistor 102 and one of the sense lines 104. The control logics 116 can be transistors, diodes or other switching elements.

Moreover, the sense lines 104 are electrically connected in parallel and all top ends of them are connected to the sense transistor 102. The memory bit 108 can be an MRAM cell, which has two ferromagnetic layers separated by a non-magnetic layer. The magnetoresistive memory 100 can further comprise at least one word line 114 electrically connected to the memory bits 108. That is, the memory bits 108 (the MRAM cells) are placed on intersections of sense lines 104 and word lines 114. In addition, the sense transistor 102 is preferably connected on the middle position of the sense lines 104, in order to optimize the signal transmission lengths of the two farthest sense lines 104.

FIG. 1B is a schematic view of another preferred embodiment of the present invention. A magnetoresistive memory 120 comprises a plurality of memory units 110 electrically connected. The memory unit 110 is similar to the magnetoresistive memory 100 as illustrated in FIG. 1A, which has a sense transistor, a plurality of sense lines and a selector as stated above. By this manner, when a greater memory capacity is required, the foregoing memory architecture of a smaller capacity can be a memory unit to extend as a memory of a greater capacity.

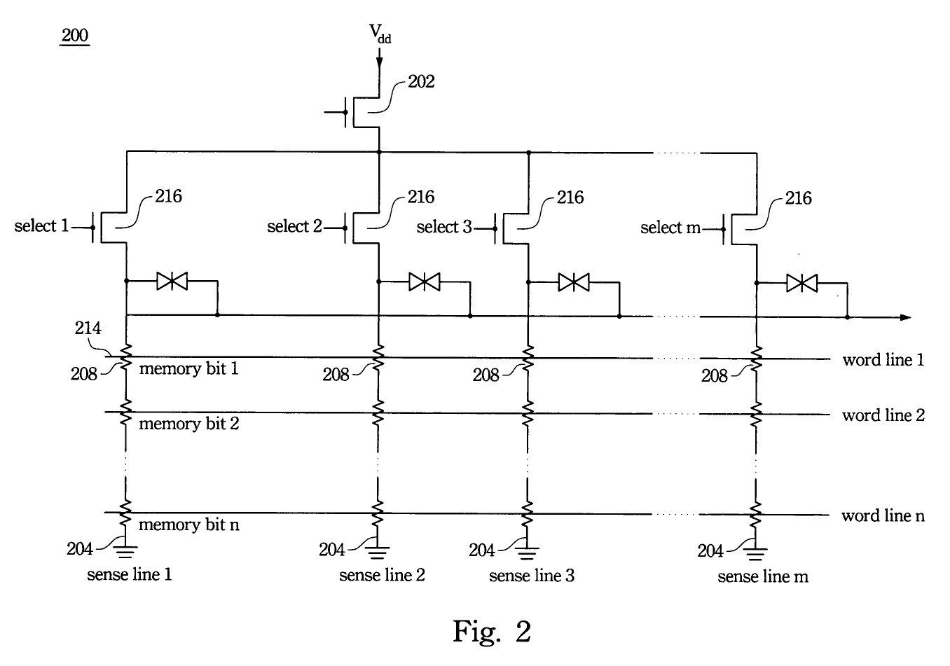

FIG. 2 is a schematic view of another preferred embodiment of the present invention. A magnetoresistive memory 200 comprises a sense transistor 202 and a plurality of sense lines 216. Each of the sense lines 204 has a control logic 216 and at least one memory bit 208. The control logic 216 is electrically connected between the sense transistor 202 and the memory bit 208.

Particularly, the magnetoresistive memory 200 has “M” sense lines 204 electrically connected in parallel, and the “M” is more than one. Each of the sense lines 204 has “N” memory bits 208 electrically connected in series, and the “N” is at least one. The control logic 216 is electrically connected to the “M” sense lines 204, and selects one of the “M” sense lines 204 for the sense transistor 202 according to select signals. The sense transistor 202 (i.e. the pull-down transistor) can access, such as reading and writing, the “N” memory bit 208 of the selected sense line 204. The control logics 216 switches the “M” sense lines 204. The control logic 216 of each sense line 204 is electrically connected between the sense transistor 202 and the memory bits 208. The control logics 116 can be a transistor, a diode or other switching element.

Moreover, the sense lines 204 are electrically connected in parallel and all top ends of them are connected to the sense transistor 202. The memory bit 208 can be an MRAM cell, which has two ferromagnetic layers separated by a non-magnetic layer. The magnetoresistive memory 200 can further comprise at least one word line 214 electrically connected to the memory bits 208. That is, the memory bits 208 (the MRAM cells) are placed on intersections of sense lines 204 and word lines 214. In addition, the sense transistor 202 is preferably connected on the middle position of the sense lines 204, in order to optimize the signal transmission lengths of the two farthest sense lines 204.

In another aspect, the above-mentioned memory architecture also can be applied to other type memories as well as MRAM. The multiple pull-down transistors of the conventional memory architecture, which are respectively configured to column lines having memory bits, can be replaced by using only one pull-down transistor coupled to all top ends of the column lines and adding a bit of minimum sized control logic to each of the column lines.

A memory comprises a plurality of memory units electrically connected. Each of the memory units comprises a pull-down transistor, a plurality of column lines and a selector. Each of the column lines has at least one bit. The selector is electrically connected between the pull-down transistor and the column lines. The selector is arranged to select one from the column lines to be accessed by the pull-down transistor.

The selector can be a tree selector or can comprise a plurality of control logics. The control logics can be transistors, diodes or other switching elements. One of the control logics is electrically connected between the pull-down transistor and one of the column lines. Moreover, the column lines are electrically connected in parallel. Each of the memory units further comprises at least one row line electrically connected to the memory bits.

In the conventional MRAM array, there is an RC network with a 6 ns delay time to see a magnetic signal. The foregoing embodiments move the sense transistor at the base of the sense lines and tie that node to ground. Only one sense transistor is left to the top end of sense lines and a bit of minimum sized control logic is added in each of the sense lines. Therefore, the RC network can be reduced to less than 1 ns. Since this time constant appears twice in the READ or WRITE cycle, the total cycle time can be reduced by almost 12 ns.

Additional gains could be found by going to a copper interconnect. This would reduce the metal resistance along those lines and allow for additional density and performance improvements. Note that portions of schematic examples are simulated and found that they are operational, passing the signal to the pre-amplifier, even at worst case.

In conclusion, by making a sense transistor do multiple duties, the size of the memory can be reduced and the performance thereof also can be improved significantly. Moreover, due to the decreasing of the sense transistors in the memory array, the number of the memory bits in each sense line can be increased. This also allows a significant increase in density of the memory.

The layout of the memory is smaller and easier to create because of a reduced circuitry requirement. The currents are easier to control to meet switching requirements for the magnetics due to smaller loads on the sense lines, Because heat is primarily dissipated through the metals, having ground connected to the sense lines reduces heat buildup. The sense lines are now isolated such that much faster operation of the memory can be utilized. Since the sense lines are now isolated, the charging and discharging of the lines is reduced resulting in significant noise reduction. The power supply voltage can be reduced because of reduced resistive devices in the sense line.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A magnetoresistive memory, comprising:
a sense transistor; and
a plurality of sense lines, wherein each of the sense lines has a control logic and at least one memory bit, and the control logic is electrically connected between the sense transistor and the memory bit.

2. The magnetoresistive memory of claim 1, wherein the control logic is a transistor or a diode.

3. The magnetoresistive memory of claim 1, further comprising at least one word line, electrically connected to the memory bits.

4. The magnetoresistive memory of claim 1, wherein the sense lines are electrically connected in parallel.

5. The magnetoresistive memory of claim 1, wherein the memory bit is an MRAM cell.

6. A magnetoresistive memory, comprising:
a sense transistor;
a plurality of sense lines, wherein each of the sense lines has at least one memory bit; and
a selector, electrically connected between the sense transistor and the sense lines, wherein the selector is arranged to select one from the sense lines to be accessed by the sense transistor.

7. The magnetoresistive memory of claim 6, wherein the selector is a tree selector.

8. The magnetoresistive memory of claim 6, wherein the selector comprises a plurality of control logics, and one of the control logics is electrically connected between the sense transistor and one of the sense lines.

9. The magnetoresistive memory of claim 8, wherein the control logics transistors or diodes.

10. The magnetoresistive memory of claim 6, further comprising at least one word line, electrically connected to the memory bits.

11. The magnetoresistive memory of claim 6, wherein the sense lines are electrically connected in parallel.

12. The magnetoresistive memory of claim 6, wherein the memory bit is an MRAM cell.

13. A magnetoresistive memory, comprising:
a plurality of memory units electrically connected, wherein each of the memory units comprises:
a sense transistor;
a plurality of sense lines, wherein each of the sense lines has at least one memory bit; and
a selector, electrically connected between the sense transistor and the sense lines, wherein the selector is arranged to select one from the sense lines to be accessed by the sense transistor.

14. The magnetoresistive memory of claim 13, wherein the selector is a tree selector.

15. The magnetoresistive memory of claim 13, wherein the selector comprises a plurality of control logics, and one of the control logics is electrically connected between the sense transistor and one of the sense lines.

16. The magnetoresistive memory of claim 15, wherein the control logics are transistors or diodes.

17. The magnetoresistive memory of claim 13, wherein each of the memory units further comprises at least one word line, electrically connected to the memory bits.

18. The magnetoresistive memory of claim 13, wherein the sense lines are electrically connected in parallel.

19. The magnetoresistive memory of claim 13, wherein the memory bit is an MRAM cell.

20. A memory, comprising:
a plurality of memory units electrically connected, wherein each of the memory units comprises:
a pull-down transistor;
a plurality of column lines, wherein each of the column lines has at least one bit; and
a selector, electrically connected between the pull-down transistor and the column lines, wherein the selector is arranged to select one from the column lines to be accessed by the pull-down transistor.

21. The memory of claim 20, wherein the selector is a tree selector.

22. The memory of claim 20, wherein the selector comprises a plurality of control logics, and one of the control logics is electrically connected between the pull-down transistor and one of the column lines.

23. The memory of claim 22, wherein the control logics are transistors or diodes.

24. The memory of claim 20, wherein each of the memory units further comprises at least one row line, electrically connected to the memory bits.

25. The memory of claim 20, wherein the column lines are electrically connected in parallel.
